(19) United States
(12) Patent Application Publication
(10) Pub. No.: US 2025/0164160 A1
(43) Pub. Date: May 22, 2025

(54) CUBOIDAL PORTABLE-SMART REFRIGERATORMETHODS AND SYSTEMS

(71) Applicant: Faizan Ahmed, San Jose, CA (US)

(72) Inventor: Faizan Ahmed, San Jose, CA (US)

(21) Appl. No.: 18/772,087

(22) Filed: Jul. 12, 2024

Related U.S. Application Data
(63) Continuation-in-part of application No. 18/374,646, filed on Sep. 28, 2023.
Application No. 18/374,646 is a continuation-in-part of application No. 18/205,488, filed on Jun. 2, 2023, now abandoned.
(63) Continuation-in-part of application No. 17/579,397, filed on Jan. 19, 2022, now abandoned.
Application No. 17/579,397 is a continuation-in-part of application No. 17/519,562, filed on Nov. 4, 2021, now abandoned.
Application No. 17/519,562 is a continuation of application No. 16/571,190, filed on Sep. 16, 2019, now abandoned.
Application No. 17/579,397 is a continuation-in-part of application No. 17/394,395, filed on Aug. 4, 2021, now abandoned.
Application No. 17/394,395 is a continuation-in-part of application No. 16/571,190, filed on Sep. 16, 2019, now abandoned.
(60) Provisional application No. 63/348,484, filed on Jun. 2, 2022.
(60) Provisional application No. 62/811,523, filed on Feb. 27, 2019.
(60) Provisional application No. 62/772,094, filed on Nov. 28, 2018.

(51) Int. Cl. F25B 21/04; F25D 11/00

(52) U.S. Cl. CPC F25B 21/04; F25D 11/00

(57) ABSTRACT

In one aspect, a cuboidal portable-smart refrigerator comprising: a payload assembly comprising: a payload space configured for storage of an item to be refrigerated; and a cooling/PCB assembly coupled with the payload space and comprising: a cooling-coil assembly comprising one or more cooling coils coupled with the thermal-chemical chamber assembly; a thermal-chemical chamber assembly that holds at least one cooling coil, wherein the thermal-chemical chamber is placed within an outer surface of the payload space; and a thermo-electric cooler pump comprising a liquid pump with an integrated chiller and an integrated heater; and a radiator assembly configured to radiate heat via one or more fans from the payload assembly; and a lid assembly configured to provide access to payload assembly.

### CLAIM OF PRIORITY

This application is a continuation in part of and claims priority to U.S. patent application Ser. No. 18/374,646, filed on Sep. 28, 2023 and titled THERMO-ELECTRIC SYSTEM COMPRISING CHAIN TRAPEZOID ELEMENTS WITH INCREASED FIGURE OF MERIT. This patent application is hereby incorporated by reference in its entirety.

U.S. patent application Ser. No. 18/374,646 is a continuation in part of and claim priority to U.S. patent application Ser. No. 18/205,488, filed on Jun. 2, 2023 and titled PORTABLE-SMART REFRIGERATOR METHODS AND SYSTEMS.

U.S. patent application Ser. No. 18/205,488 claims priority to and incorporates by reference in its entirety U.S. Application No. 63/348,484 and filed on 2 Jun. 2022 and PORTABLE-SMART REFRIGERATOR METHODS AND SYSTEMS. This patent application is hereby incorporated by reference in its entirety.

This application is a continuation in part of and claims priority to U.S. patent application Ser. No. 17/579,397, filed on Jan. 19, 2022 and titled PORTABLE-SMART REFRIGERATOR METHODS AND SYSTEMS. This patent application is hereby incorporated by reference in its entirety.

U.S. patent application Ser. No. 17/579,397 is a continuation in-part of U.S. patent application Ser. No. 17/519,562 filed on Nov. 4, 2021. This patent application is hereby incorporated by reference in its entirety.

U.S. patent application Ser. No. 17/519,562 is a continuation of U.S. patent application Ser. No. 16/571,190 filed on Sep. 16, 2019. This patent application is hereby incorporated by reference in its entirety.

U.S. patent application Ser. No. 16/571,190 claims priority from U.S. provisional application 62/811,523 filed on Feb. 27, 2019. This patent application is hereby incorporated by reference in its entirety.

U.S. patent application Ser. No. 16/571,190 claims priority from U.S. provisional application 62/772,094 filed on Nov. 28, 2018. This patent application is hereby incorporated by reference in its entirety.

U.S. patent application Ser. No. 17/579,397 is a continuation in-part of U.S. patent application Ser. No. 17/394,395 filed on Aug. 4, 2021. This patent application is hereby incorporated by reference in its entirety.

U.S. patent application Ser. No. 17/394,395 is a continuation in-part of U.S. patent application Ser. No. 16/571,190 filed on Sep. 16, 2019. This patent application is hereby incorporated by reference in its entirety.

U.S. patent application Ser. No. 16/571,190 claims priority from a U.S. provisional application No. 62/811,523 filed on Feb. 27, 2019. This patent application is hereby incorporated by reference in its entirety.

These applications are hereby incorporated by reference in their entirety.

### BACKGROUND

### Field of the Invention

The invention is in the field of refrigeration and more specifically to a method, system and apparatus of a cuboidal portable-smart refrigerator.

### Description of the Related Art

Medicines and other products can degrade in certain conditions. For example, some temperatures need to be maintained in specified temperature ranges. Patients may not be able to constantly track medicine temperature. The same can be true for some testing instruments such as blood testing strips. Portable refrigerators can solve these issues. However, effective portable refrigerators need effective components that are sufficient. Accordingly, improvements to thermo-electric cooler pump design and use are desired.

### BRIEF SUMMARY OF THE INVENTION

In one aspect, a cuboidal portable-smart refrigerator comprising: a payload assembly comprising: a payload space configured for storage of an item to be refrigerated; and a cooling/PCB assembly coupled with the payload space and comprising: a cooling-coil assembly comprising one or more cooling coils coupled with the thermal-chemical chamber assembly; a thermal-chemical chamber assembly that holds at least one cooling coil, wherein the thermal-chemical chamber is placed within an outer surface of the payload space; and a thermo-electric cooler pump comprising a liquid pump with an integrated chiller and an integrated heater; and a radiator assembly configured to radiate heat via one or more fans from the payload assembly; and a lid assembly configured to provide access to payload assembly.

### BRIEF DESCRIPTION OF THE DRAWINGS

FIG. 1 is a top view of the portable-smart refrigerator, according to some embodiments.

FIG. 2 is bottom view of the portable-smart refrigerator, according to some embodiments.

FIG. 3 is a front view of the portable-smart refrigerator, according to some embodiments.

FIG. 4 is a side view of the portable-smart refrigerator, according to some embodiments.

FIG. 5 is a back view of the portable-smart refrigerator, according to some embodiments.

FIG. 6 is a perspective view of the portable-smart refrigerator, according to some embodiments.

FIG. 7 illustrates an exploded view of an example portable-smart refrigerator lid assembly, according to some embodiments.

FIG. 8 illustrates an example portable-smart refrigerator grill assembly, according to some embodiments.

FIG. 9 illustrates an example assembled grill assembly, according to some embodiments.

FIG. 10 illustrates an example portable-smart refrigerator cooling-coil assembly, according to some embodiments.

FIGS. 11A-B illustrate an example portable-smart refrigerator cooling-coil assembly, according to some embodiments.

FIG. 12 illustrates an example portable-smart refrigerator thermal-chemical chamber assembly, according to some embodiments.

FIG. 13 illustrates another view of an example portable-smart refrigerator thermal-chemical chamber assembly, according to some embodiments.

FIG. 14 illustrates an example portable-smart refrigerator sleeve assembly, according to some embodiments.

FIG. 15 illustrates an example exploded view of a portable-smart refrigerator assembly, according to some embodiments.

FIG. 16 illustrates an example exploded view of a portable-smart refrigerator heat seat system, according to some embodiments.

FIG. 17 illustrates an example view of a portable-smart refrigerator assembly, according to some embodiments.

FIG. 18 illustrates an example interior view of a pump/coil/heat sink assembly, according to some embodiments.

FIG. 19 is a block diagram of a sample computing environment that can be utilized to implement various embodiments.

FIG. 20 is a first exterior view of a cuboidal portable-smart refrigerator, according to some embodiments.

FIG. 21 is a second exterior view of the cuboidal portable-smart refrigerator, according to some embodiments.

FIG. 22 is a third exterior view of the cuboidal portable-smart refrigerator, according to some embodiments.

FIG. 23 is a fourth exterior view of the cuboidal portable-smart refrigerator, according to some embodiments.

FIG. 24 is a fourth exterior view of the cuboidal portable-smart refrigerator, according to some embodiments.

FIG. 25 illustrates an example exploded view of a cuboidal portable-smart refrigerator, according to some embodiments.

The Figures described above are a representative set and are not an exhaustive with respect to embodying the invention.

### DESCRIPTION

Disclosed are a system, method, and article of manufacture for a cuboidal portable-smart refrigerator. The following description is presented to enable a person of ordinary skill in the art to make and use the various embodiments. Descriptions of specific devices, techniques, and applications are provided only as examples. Various modifications to the examples described herein can be readily apparent to those of ordinary skill in the art, and the general principles defined herein may be applied to other examples and applications without departing from the spirit and scope of the various embodiments.

Reference throughout this specification to ‘one embodiment,’ ‘an embodiment,’ ‘one example,’ or similar language means that a particular feature, structure, or characteristic described in connection with the embodiment is included in at least one embodiment, according to some embodiments. Thus, appearances of the phrases ‘in one embodiment,’ ‘in an embodiment,’ and similar language throughout this specification may, but do not necessarily, all refer to the same embodiment.

Furthermore, the described features, structures, or characteristics of the invention may be combined in any suitable manner in one or more embodiments. In the following description, numerous specific details are provided, such as examples of programming, software modules, user selections, network transactions, database queries, database structures, hardware modules, hardware circuits, hardware chips, etc., to provide a thorough understanding of embodiments of the invention. One skilled in the relevant art can recognize, however, that the invention may be practiced without one or more of the specific details, or with other methods, components, materials, and so forth. In other instances, well-known structures, materials, or operations are not shown or described in detail to avoid obscuring aspects of the invention.

The schematic flow chart diagrams included herein are generally set forth as logical flow chart diagrams. As such, the depicted order and labeled steps are indicative of one embodiment of the presented method. Other steps and methods may be conceived that are equivalent in function, logic, or effect to one or more steps, or portions thereof, of the illustrated method. Additionally, the format and symbols employed are provided to explain the logical steps of the method and are understood not to limit the scope of the method. Although various arrow types and line types may be employed in the flow chart diagrams, and they are understood not to limit the scope of the corresponding method. Indeed, some arrows or other connectors may be used to indicate only the logical flow of the method. For instance, an arrow may indicate a waiting or monitoring period of unspecified duration between enumerated steps of the depicted method. Additionally, the order in which a particular method occurs may or may not strictly adhere to the order of the corresponding steps shown.

### Definitions

Example definitions for some embodiments are now provided.

Acrylonitrile butadiene styrene (ABS) is a common plastic polymer.

High-density polyethylene (HDPE) or polyethylene high-density (PEHD) is a polyethylene thermoplastic made from petroleum.

Peltier effect is the presence of heating or cooling at an electrified junction of two different conductors. When a current is made to flow through a junction between two conductors, A and B, heat may be generated or removed at the junction. Thermoelectric cooling uses the Peltier effect to create a heat flux between the junction of two different types of materials. A Peltier cooler, heater, or thermoelectric heat pump is a solid-state active heat pump which transfers heat from one side of the device to the other, with consumption of electrical energy, depending on the direction of the current.

Thermal-chemical is a substance with a high heat of fusion which, melting and solidifying at a certain temperature, is capable of storing and releasing large amounts of energy. Heat is absorbed or released when the material changes from solid to liquid and vice versa.

Polypropylene (PP) is a thermoplastic polymer used in a wide variety of applications. It is produced via chain-growth polymerization from the monomer propylene.

Press fit or friction fit is a fastening between two parts which is achieved by friction after the parts are pushed together, rather than by any other means of fastening.

Temperature sensors can include mechanical temperature sensors, electrical temperature sensors, integrated circuit sensors, medometers, etc.

Thermoelectric effect is the direct conversion of temperature differences to electric voltage and vice versa via a thermocouple. A thermoelectric device creates voltage when there is a different temperature on each side. Conversely, when a voltage is applied to it, heat is transferred from one side to the other, creating a temperature difference. At the atomic scale, an applied temperature gradient causes charge carriers in the material to diffuse from the hot side to the cold side.

### Example Smart Refrigerator Exterior Views

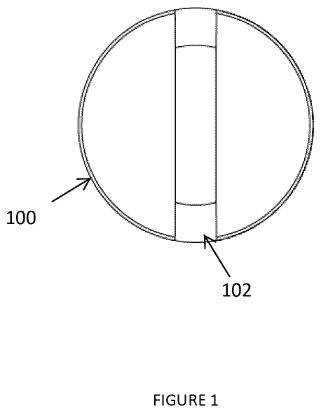

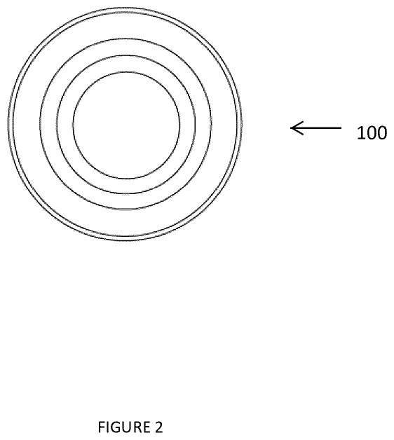

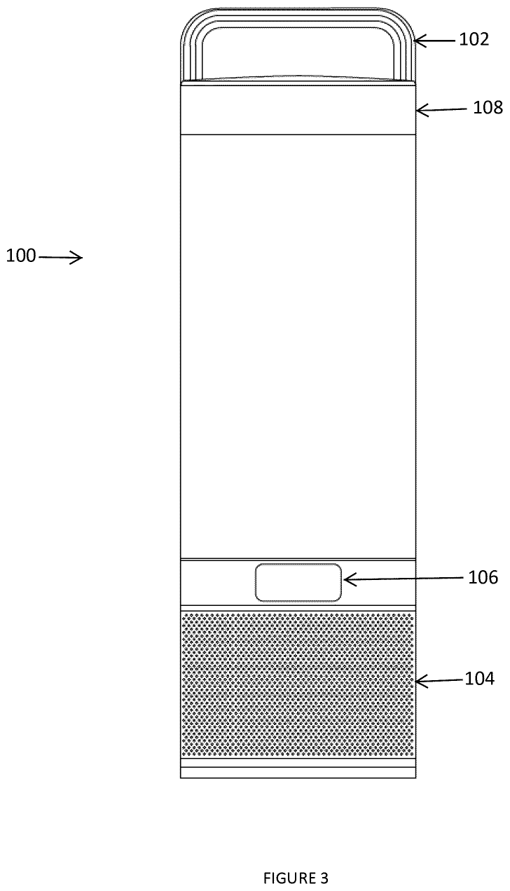

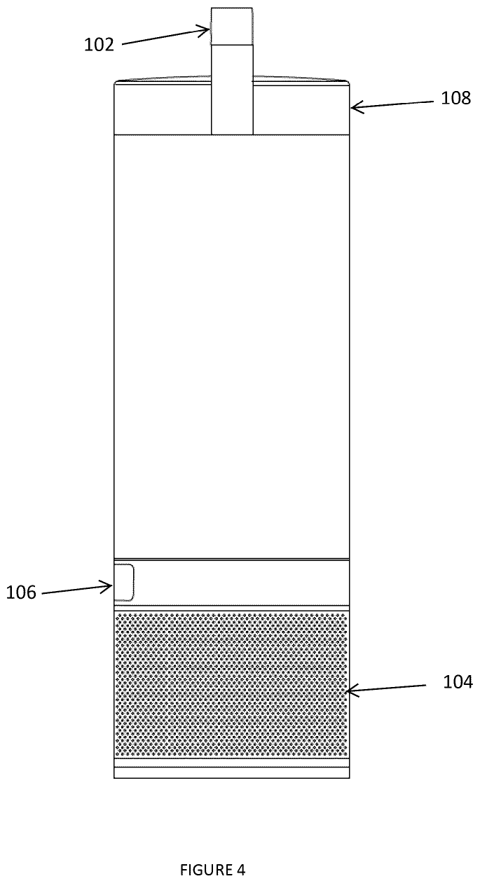

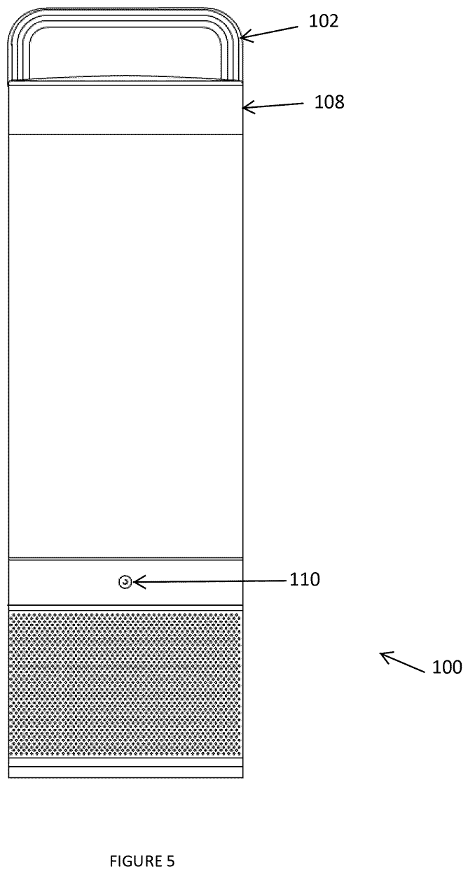

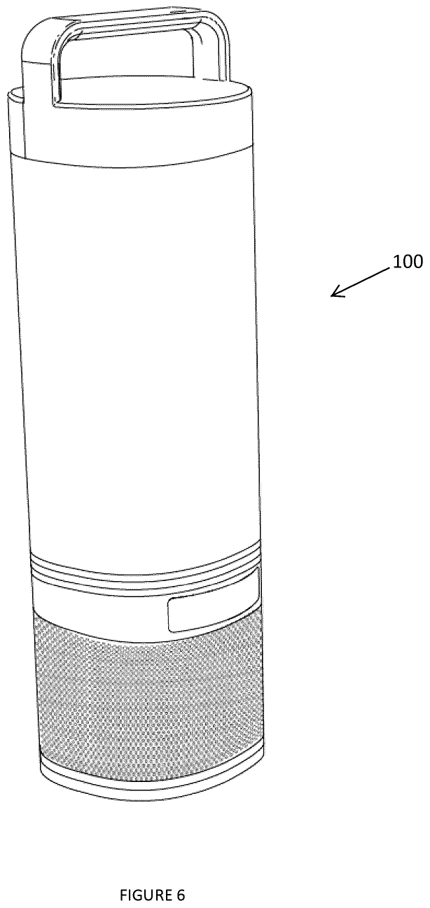

FIG. 1 is a top view of the portable-smart refrigerator 100, according to some embodiments. The lid 108 of portable-smart refrigerator 100 includes a handle 102. FIG. 2 is bottom view of the portable-smart refrigerator, according to some embodiments. FIG. 3 is a front view of the portable-smart refrigerator, according to some embodiments. Portable-smart refrigerator 100 includes an exterior user display/interface 106. Portable-smart refrigerator 100 includes a grill exterior 104. Grill exterior 104 can enable the inflow of air and/or outflow of heat to and from various interior systems portable-smart refrigerator 100. FIG. 4 is a side view of the portable-smart refrigerator, according to some embodiments. FIG. 5 is a back view of the portable-smart refrigerator, according to some embodiments. FIG. 6 is a perspective view of the portable-smart refrigerator, according to some embodiments.

### Example Smart Refrigerator Assembly

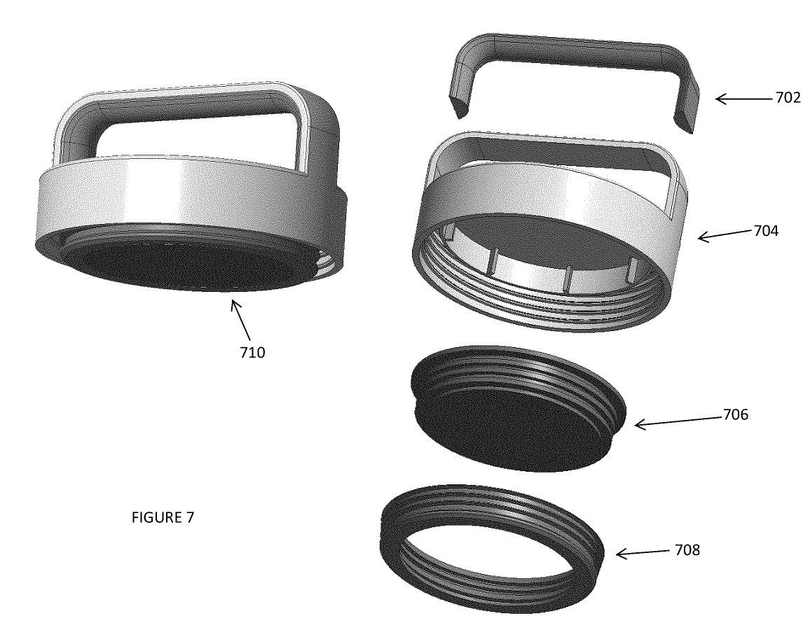

FIG. 7 illustrates an exploded view of an example portable-smart refrigerator lid assembly 700, according to some embodiments. Portable-smart refrigerator lid assembly 700 can be utilized to form lid 108 discussed supra. Portable-smart refrigerator lid assembly 700 includes handle 702. Handle 702 can be a lid over mold made of ABS. Portable-smart refrigerator lid assembly 700 includes lid 704. Handle 702 is connected with lid 704 as shown. Lid 704 can be a mold made of ABS. Portable-smart refrigerator lid assembly 700 includes lid bottom cover 706. Lid bottom cover 706 is coupled with the lid silicone seal 708. Lid bottom cover 706 and lid silicone seal 708 have a helical ridge (a male thread) for fastening portable-smart refrigerator lid assembly 700 to an internal upper portion of portable-smart refrigerator 100 with a corresponding female thread (not shown). An assembled version 710 of portable-smart refrigerator lid assembly 700 is also shown.

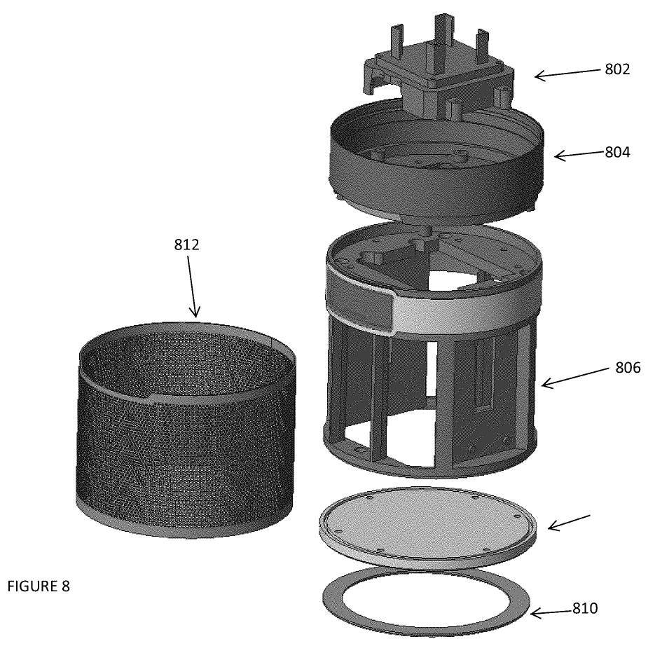

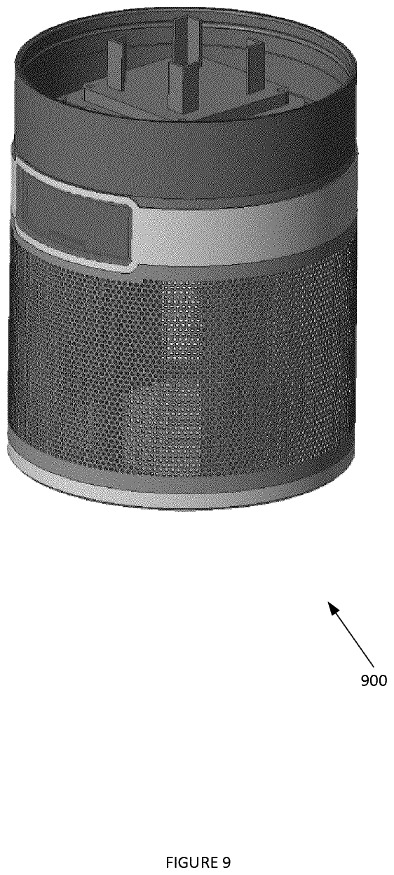

FIG. 8 illustrates an example portable-smart refrigerator grill assembly 800, according to some embodiments. Portable-smart refrigerator grill assembly 800 includes pump bracket 802. Portable-smart refrigerator grill assembly 800 includes top base 804. Top base 804 holds pump bracket 802. Portable-smart refrigerator grill assembly 800 includes middle base 806. Portable-smart refrigerator grill assembly 800 includes bottom base 808. Bottom base 808 includes a silicone seal. Pump bracket 802, middle base 806, bottom base 808 can be an ABS material. Top base 804 can be a PP material. Grill exterior 104 is provided as an exterior of an assembled of portable-smart refrigerator grill assembly 800. FIG. 9 illustrates an example assembled grill assembly, according to some embodiments.

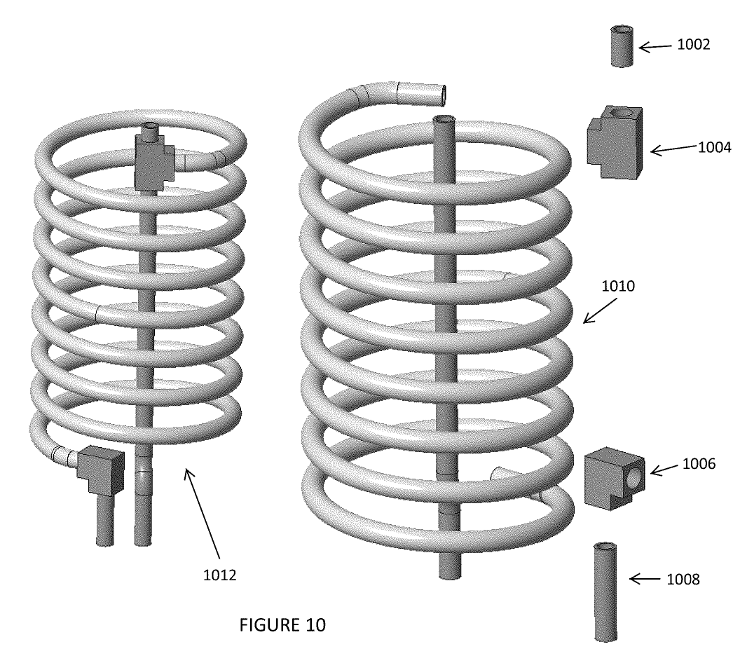

FIG. 10 illustrates an example portable-smart refrigerator cooling-coil assembly 1000, according to some embodiments. Portable-smart refrigerator cooling-coil assembly 1000 includes feeding tube 1002. Portable-smart refrigerator cooling-coil assembly 1000 includes top elbow 1004. Top elbow 1004 can elbow is installed between two lengths of tubing/pipe to allow a change of direction. Portable-smart refrigerator cooling-coil assembly 1000 includes bottom elbow 1006. Top elbow 1004 and bottom elbow 1006 can be made of copper. Portable-smart refrigerator cooling-coil assembly 1000 includes bottom tube 1008. Portable-smart refrigerator cooling-coil assembly 1000 includes cooling coil 1010. Portable-smart refrigerator cooling-coil assembly 1000 includes vertical tube 1012. The tube/pipes of portable-smart refrigerator cooling-coil assembly 1000 can be made of copper, in some example embodiments. For example, copper tubing can be of 8 mm outer/6 mm inner D. An assembled version 1014 of portable-smart refrigerator cooling-coil assembly 1000 is also shown.

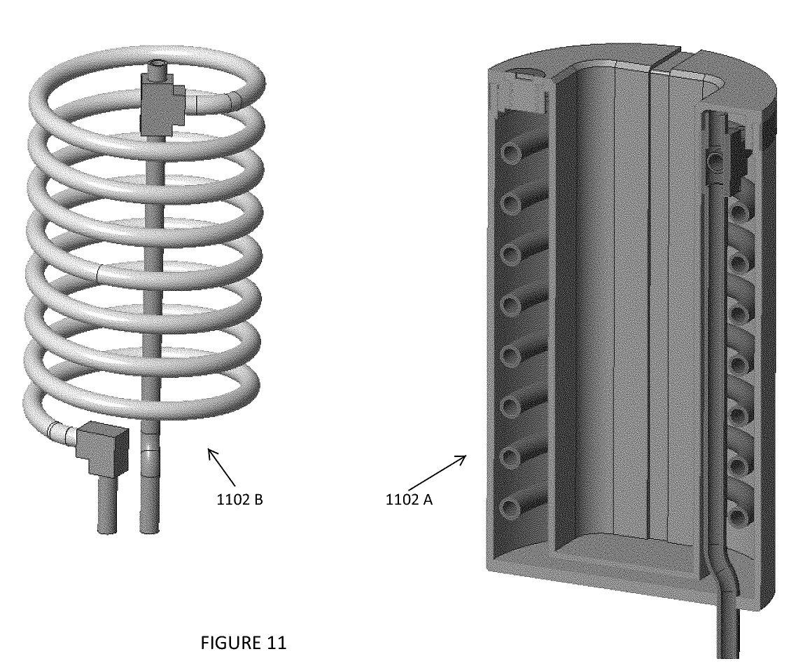

FIGS. 11A-B illustrate an example portable-smart refrigerator cooling-coil assembly 1000, according to some embodiments. FIG. 11A illustrates soldering of top elbow 1004 and bottom elbow 1006 to cooling coil 1010, according to some embodiments. FIG. 11 B illustrates a cross-section view of portable-smart refrigerator cooling-coil assembly 1000 installed into a thermal-chemical chamber, according to some embodiments.

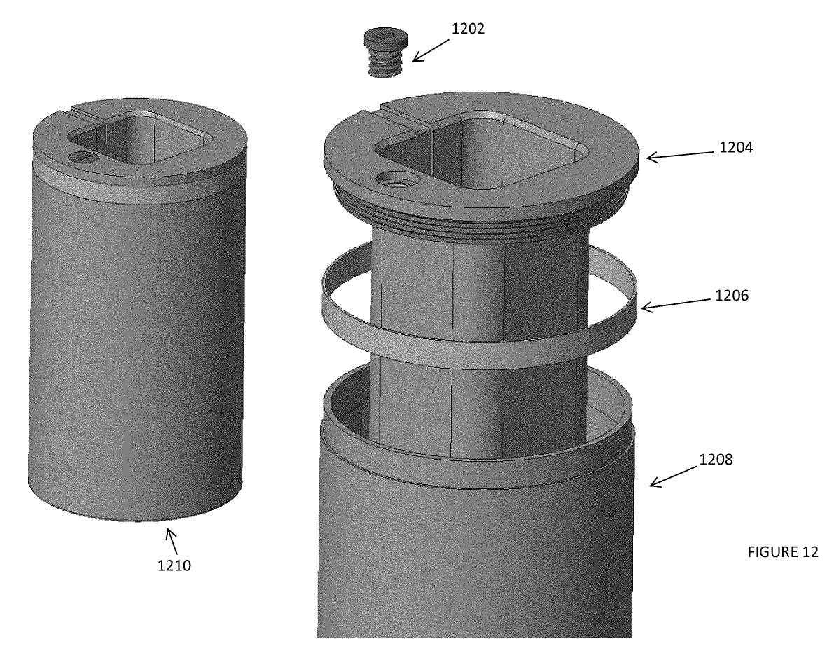

FIG. 12 illustrates an example portable-smart refrigerator thermal-chemical chamber assembly 1200, according to some embodiments. Portable-smart refrigerator thermal-chemical chamber assembly 1200 includes cork 1202. Cork 1202 can be made of HDPE material. Portable-smart refrigerator thermal-chemical chamber assembly 1200 includes top material of thermal-chemical chamber 1204. Top material of thermal-chemical chamber 1204 can be made of HDPE material. Portable-smart refrigerator thermal-chemical chamber assembly 1200 includes compression ring 1206 can be stainless steel. Compression ring 1206 is metal seals that fits between the portable-smart refrigerator thermal-chemical chamber and smart-fridge cylinder. Compression ring 1206 fits into a groove around the outer diameter of portable-smart refrigerator thermal-chemical chamber. Portable-smart refrigerator thermal-chemical chamber assembly 1200 includes bottom material portion of thermal-chemical chamber 1208. The bottom material portion of thermal-chemical chamber 1208 can be made of a HDPE material. The interfaces between coils and plastic apertures/openings can include water-tight sealants. An assembled version 1210 of portable-smart refrigerator thermal-chemical chamber assembly 1200 is also shown.

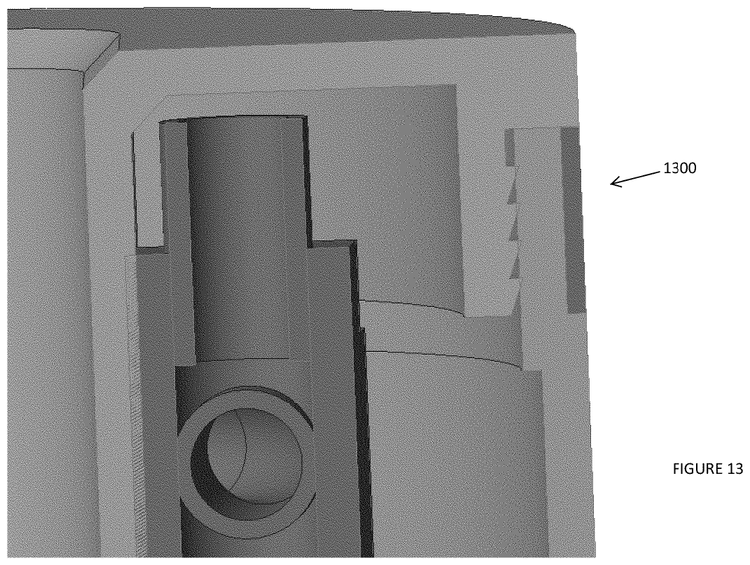

FIG. 13 illustrates another view of an example portable-smart refrigerator thermal-chemical chamber assembly 1300, according to some embodiments. As shown, the cooling coil can be installed into the bottom part of the thermal-chemical chamber. The top part is then assembled using a press/interference fit 1302. In 1304, compression ring 1206 is used to prevent deformation in the press fit area.

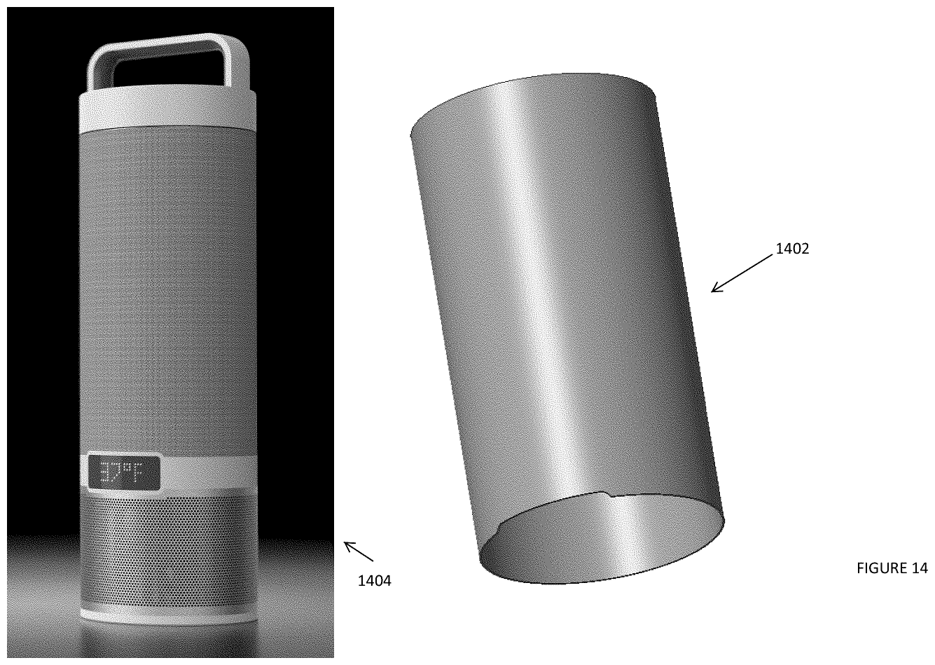

FIG. 14 illustrates an example portable-smart refrigerator sleeve assembly 1400, according to some embodiments. Portable-smart refrigerator sleeve assembly 1400 includes a fabric sleeve 1402. Fabric sleeve 1402 can be made of a stretchable material. An assembled version 1404 of portable-smart refrigerator sleeve assembly 1400 is also shown. Assembled version 1404 comprises an example image of portable-smart refrigerator 100.

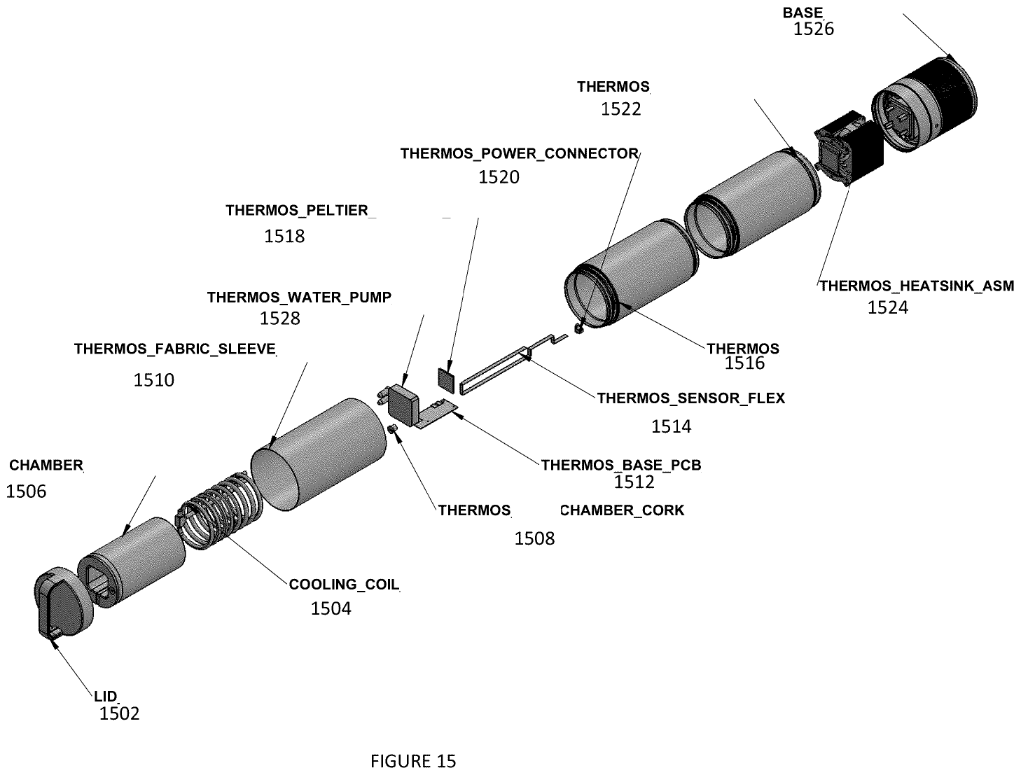

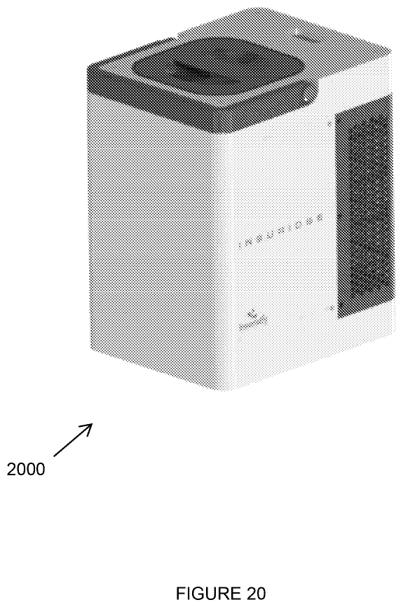

FIG. 15 illustrates an example exploded view 1500 of a portable-smart refrigerator assembly, according to some embodiments. Exploded view 1500 illustrates an example assembly of lid 1502, cooling coil 1504, chamber 1506 (e.g. can be a thermal-chemical chamber, etc.), thermos chamber cork 1508, thermos fabric sleeve 1510, thermos water pump 1528, thermos base PCB 1512, thermos sensor flex 1514, thermos 1516, thermos Peltier 1518, thermos power connector 1520, thermos, 1522, thermos heat sink ASM 1524, base 1516, etc. It is noted that portable-smart refrigerator assembly shown in FIG. 15 can be adapted to a cuboidal form and integrated into the cuboidal portable-smart refrigerator of FIGS. 20-25 by way of example.

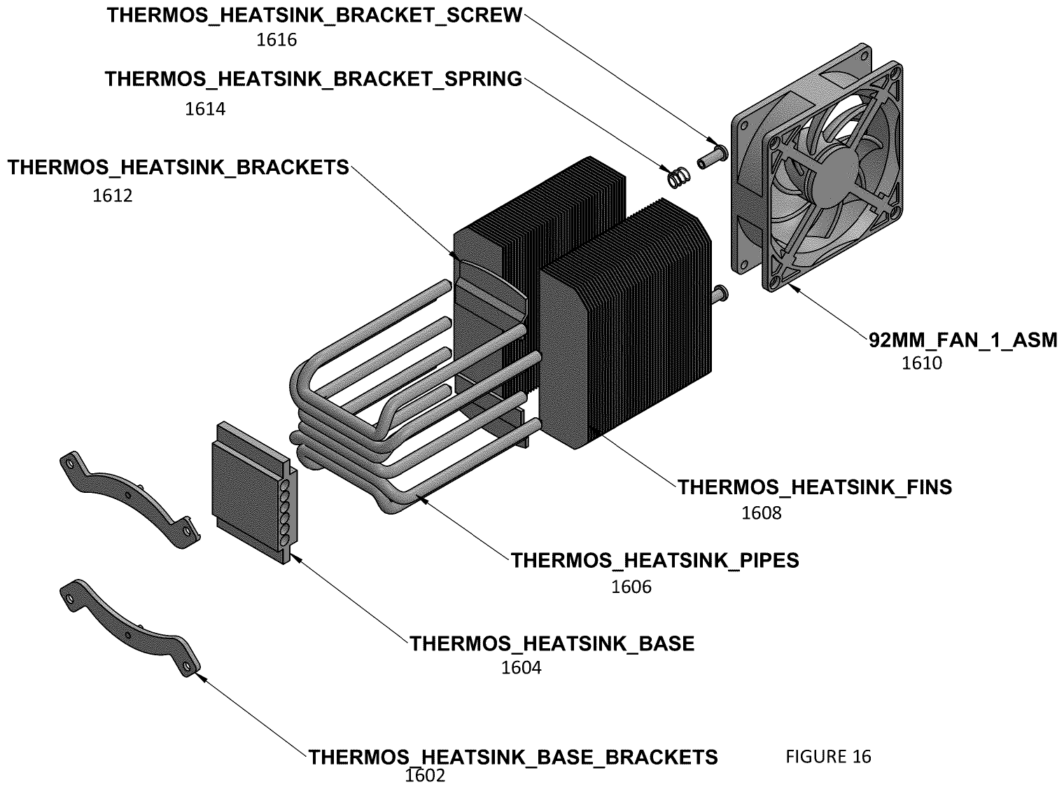

FIG. 16 illustrates an example exploded view of a portable-smart refrigerator heat seat system 1600, according to some embodiments. Thermos heat sink base brackets 1602, thermos heat sink base1604, thermos heat sink pipes 1606, thermos heat sink fins 1608, fan 1610, thermos heat sink brackets 1612, thermos heat sink bracket spring 1614 and thermos heat sink bracket screw 1616.

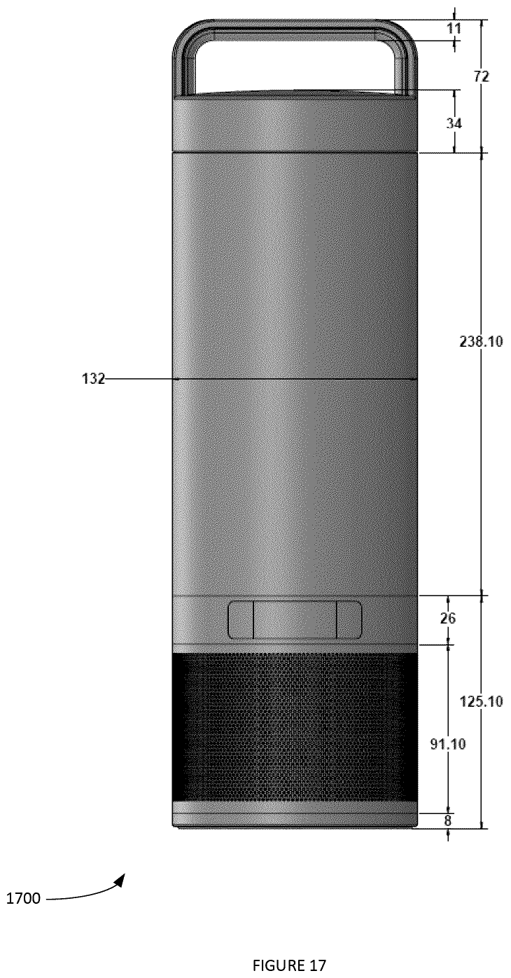

FIG. 17 illustrates an example view 1700 of a portable-smart refrigerator assembly, according to some embodiments. Example view 1700 illustrates an example set of dimension measurements in terms of millimeters. This example is provided by way of illustration and not of limitation.

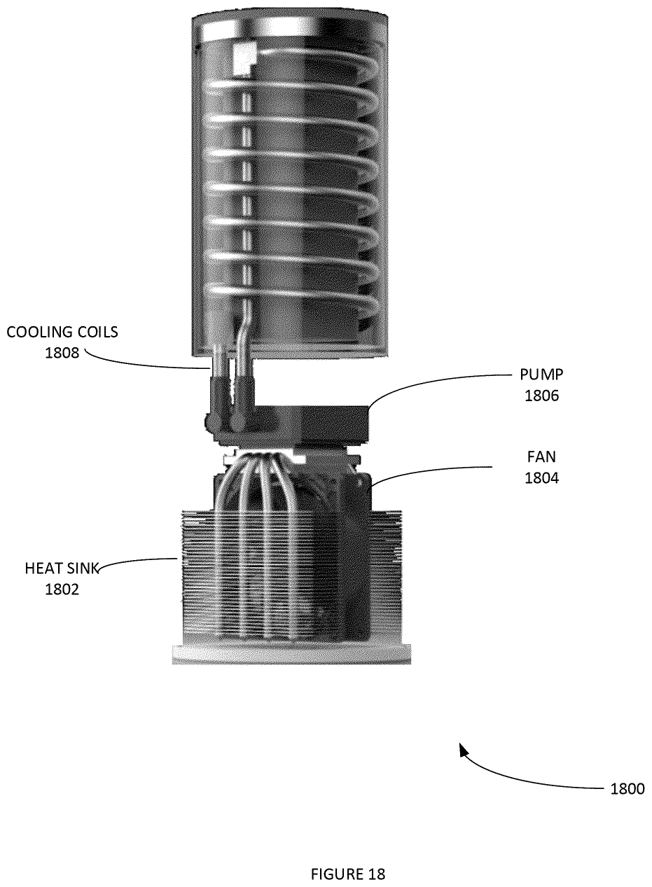

FIG. 18 illustrates an example interior view of a pump/coil/heat sink assembly 1800, according to some embodiments. Pump/coil/heat sink assembly 1800 includes heat sink 1802 coupled with fan 1804. Pump 1806 can be a thermo-electric cooler pump and pump a coolant through cooling coils 1808. In this way, portable-smart refrigerator assembly can be cooled and maintain a specified temperature range.

### Example Computer Architecture and Systems

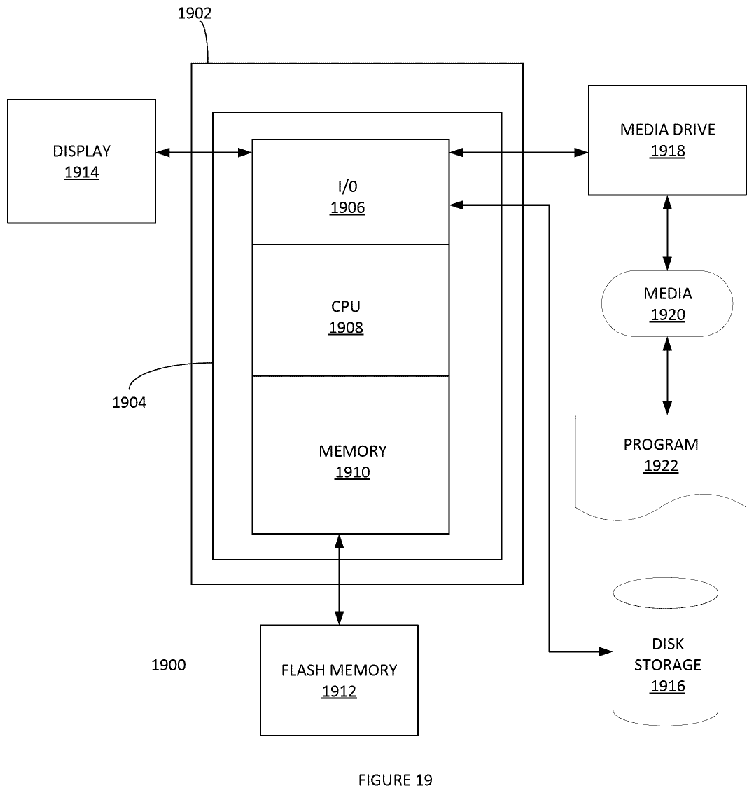

FIG. 19 depicts an exemplary computing system 1900 that can be configured to perform any one of the processes provided herein. In this context, computing system 1900 may include, for example, a processor, memory, storage, and I/O devices (e.g., monitor, keyboard, disk drive, Internet connection, etc.). However, computing system 1900 may include circuitry or other specialized hardware for carrying out some or all aspects of the processes. In some operational settings, computing system 1900 may be configured as a system that includes one or more units, each of which is configured to carry out some aspects of the processes either in software, hardware, or some combination thereof.

FIG. 19 depicts computing system 1900 with a number of components that may be used to perform any of the processes described herein. The main system 1902 includes a motherboard 1904 having an I/O section 1906, one or more central processing units (CPU) 1908, and a memory section 1910, which may have a flash memory card 1912 related to it. The I/O section 1906 can be connected to a display 1914, a keyboard and/or other user input (not shown), a disk storage unit 1916, and a media drive unit 1918. The media drive unit 1918 can read/write a computer-readable medium 1920, which can contain programs 1922 and/or data. Computing system 1900 can include a web browser. Moreover, it is noted that computing system 1900 can be configured to include additional systems in order to fulfill various functionalities. Computing system 1900 can communicate with other computing devices based on various computer communication protocols such a Wi-Fi, Bluetooth® (and/or other standards for exchanging data over short distances includes those using short-wavelength radio transmissions), USB, Ethernet, cellular, an ultrasonic local area communication protocol, etc.

The portable smart refrigerator can include a thermo-electric cooler pump as provided in U.S. patent application Ser. No. 16/523,827, titled THERMO-ELECTRIC COOLER PUMP METHODS AND SYSTEMS and filed on 26 Jul. 2019, which is incorporated herein by reference in its entirety. Thermo-electric cooler pump (not shown) includes a liquid pump with integrated chiller and heater. This liquid can be pushed through coiling assembly. The liquid pump with integrated chiller includes four components. The case component seals the liquid so that the liquid does not escape except by the inlet port and exit port which are also formed by case.

The motor component situated outside of the case, is not wetted by the liquid, and is fixed to the Case by attachments such as screws. A shaft of the motor enters the case through a sealed hole.

The impeller is contained within the case. The impeller is wetted by the liquid. The impeller is attached to shaft such that the motion of motor is transferred to impeller causing it to move. The movement of impeller causes liquid to enter the inlet port and move toward the exit port. The movement of the liquid is directed from inlet to exit port by the geometry of case and impeller. The chiller/heater is fixed to the case by attachments such as screws. Chiller/Heater penetrates the case such that one part of chiller/heater is inside the case and is wetted by liquid while the other part of chiller/heater is outside of the case and is dry. There is a seal around chiller/heater so that liquid does not escape in the vicinity of the chiller/heater. Chiller/Heater converts electron flow to thermal heat transfer by means of the Peltier effect. When electrons are made to flow in the positive direction, the wetted side of chiller/heater is driven to lower temperatures and the dry side to higher temperature. The Peltier effect causes heat to flow from cold side to hot side and is reversible with a reversal in electron flow.

Thermo-electric cooler pump can be managed by a computing system in the portable smart refrigerator. The computing system can be coupled with an exterior display. Exterior display can display various parameters (e.g. temperature, batter power, etc.) of the portable smart refrigerator. Computing system can also be coupled with various other systems such as, inter alia: temperature sensors, digital clocks, Wi-Fi systems, etc.

### Cuboidal Portable-Smart Refrigerator

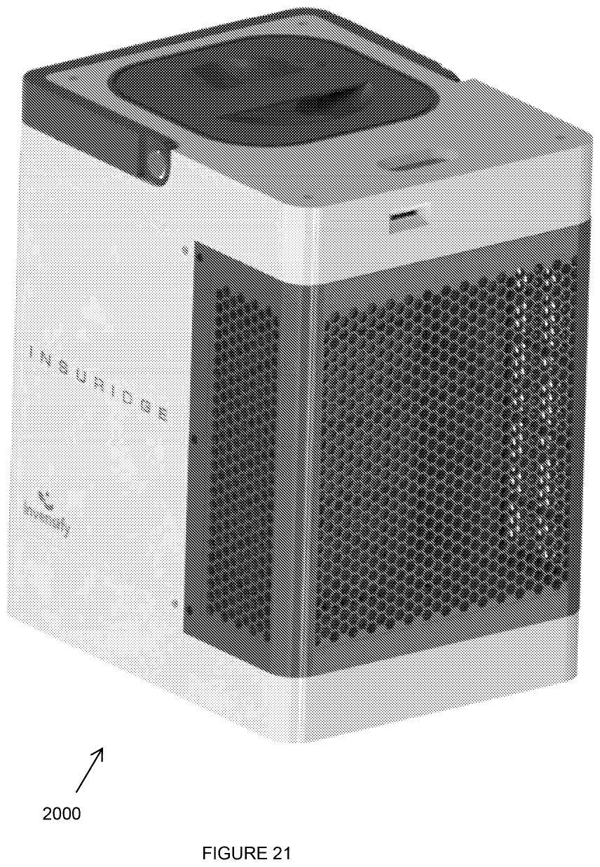

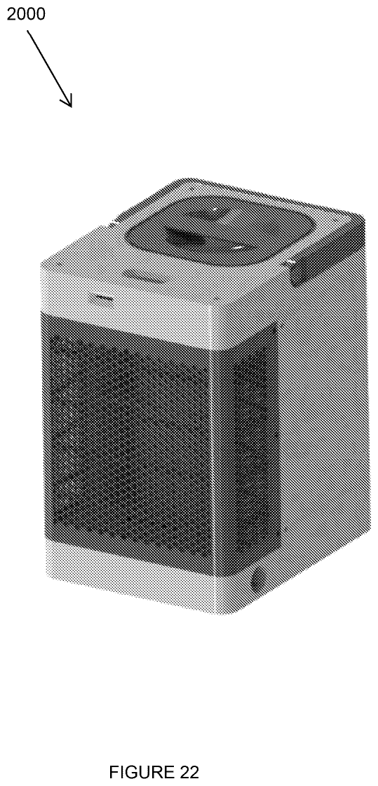

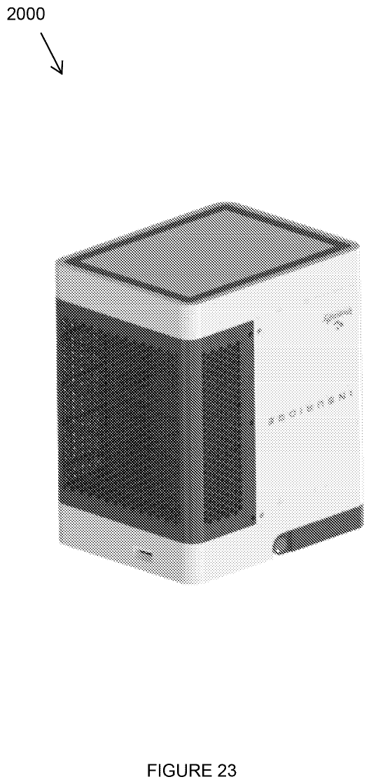

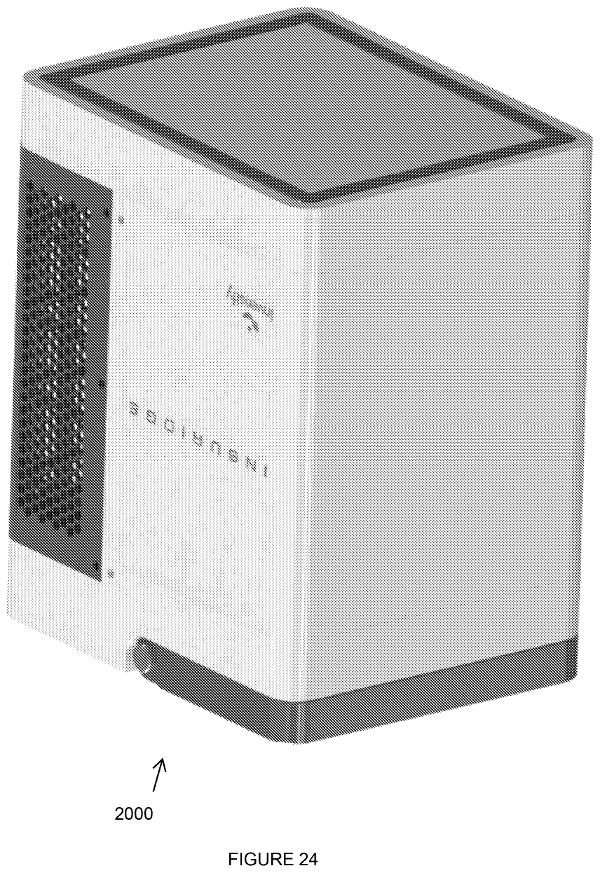

FIG. 20 is a first exterior view of a cuboidal portable-smart refrigerator 2000, according to some embodiments. FIG. 21 is a second exterior view of the cuboidal portable-smart refrigerator 2000, according to some embodiments. FIG. 22 is a third exterior view of the cuboidal portable-smart refrigerator 2000, according to some embodiments. FIG. 23 is a fourth exterior view of the cuboidal portable-smart refrigerator 2000, according to some embodiments. FIG. 24 is a fourth exterior view of the cuboidal portable-smart refrigerator 2000, according to some embodiments.

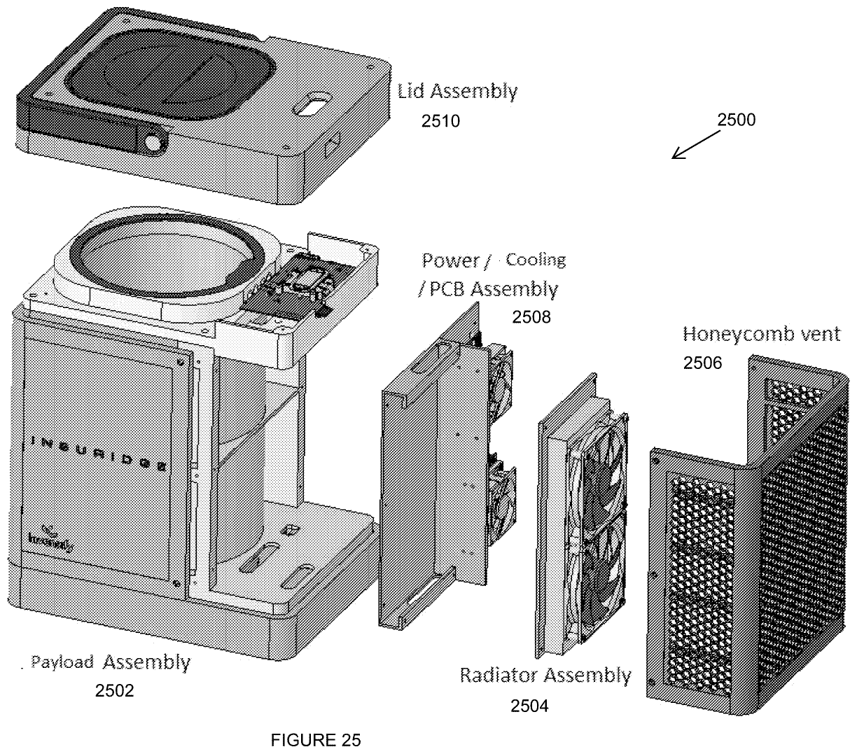

FIG. 25 illustrates an example exploded view of a cuboidal portable-smart refrigerator 2500, according to some embodiments. External portions of the cuboidal portable-smart refrigerator 2500 can be provided as shown in FIGS. 20-24. Cuboidal portable-smart refrigerator 2500 includes, inter alia, a payload assembly 2502, a cooling/PCB assembly 2508, a radiator assembly 2506 a lid assembly 2510, and a honeycomb vent 2506. Payload assembly 2502 can include a space for holding temperature-controlled items such as medicine. As noted supra, payload assembly 2502 can include modified versions of a thermal-chemical chamber assembly (e.g. as discussed supra), etc.

Cooling/PCB assembly 2508 can maintained the space in the payload assembly 2502 at a specified temperature range. As noted supra, Cooling/PCB assembly 2508 can include modified versions of a cooling-coil assembly (e.g. as discussed supra). In one example, cooling-coil assembly can include various cooling coils. By way of example, cooling-coil assembly can include, inter alia: a feeding tube, a top elbow, a bottom tube, a cooling coil (e.g. wrapping around the shape of the payload space that itself can be any shape such as a cube, a cylinder, etc.). The top elbow can be installed between n-lengths of tubing/pipe to enable a change of direction and couples the feeding tube with the cooling coil. The cooling coil can be coupled with the bottom tube. The thermal-chemical chamber assembly that holds the cooling coil. The thermal-chemical chamber is placed within an outer surface of the payload space of the payload assembly 2502. A thermo-electric cooler pump comprising a liquid pump with an integrated chiller and an integrated heater can be used to control the temperature of the payload space. Radiator assembly 2506 can radiate heat (e.g. via fans, etc.) from the payload assembly 2502. Lid assembly can provide access to payload assembly 2502. Honeycomb vent 2506 can protect access to the radiator assembly while enabling the removal of heat.

### CONCLUSION

Although the present embodiments have been described with reference to specific example embodiments, various modifications and changes can be made to these embodiments without departing from the broader spirit and scope of the various embodiments. For example, the various devices, modules, etc. described herein can be enabled and operated using hardware circuitry, firmware, software or any combination of hardware, firmware, and software (e.g., embodied in a machine-readable medium).

In addition, it can be appreciated that the various operations, processes, and methods disclosed herein can be embodied in a machine-readable medium and/or a machine accessible medium compatible with a data processing system (e.g., a computer system), and can be performed in any order (e.g., including using means for achieving the various operations). Accordingly, the specification and drawings are to be regarded in an illustrative rather than a restrictive sense. In some embodiments, the machine-readable medium can be a non-transitory form of machine-readable medium.

1. A cuboidal portable-smart refrigerator comprising:
a payload assembly comprising:
a payload space configured for storage of an item to be refrigerated; and
a cooling/PCB assembly coupled with the payload space and comprising:
a cooling-coil assembly comprising one or more cooling coils coupled with the thermal-chemical chamber assembly;
a thermal-chemical chamber assembly that holds at least one cooling coil, wherein the thermal-chemical chamber is placed within an outer surface of the payload space; and
a thermo-electric cooler pump comprising a liquid pump with an integrated chiller and an integrated heater; and
a radiator assembly configured to radiate heat via one or more fans from the payload assembly; and
a lid assembly configured to provide access to payload assembly.

2. The portable-smart refrigerator of claim 1, wherein the portable-smart refrigerator is cuboidal in shape.

3. The portable-smart refrigerator of claim 2, wherein the item to be refrigerated comprises a medicine.

4. The portable-smart refrigerator of claim 3, wherein the liquid is cooled utilized a Peltier effect system in the thermo-electric cooler pump.

5. The portable-smart refrigerator of claim 4, wherein the Cooling/PCB assembly maintains the space in the payload assembly at a specified temperature range.

6. The portable-smart refrigerator of claim 5 further comprising:
a honeycomb vent coupled with the radiator assembly.

7. The portable-smart refrigerator of claim 6, wherein the honeycomb vent protects access to the radiator assembly while enabling the removal of heat by the radiator assembly.
